(19) United States
(12) Patent Application Publication
(10) Pub. No.: US 2014/0356995 A1
(43) Pub. Date: Dec. 4, 2014

(54) METHOD FOR FABRICATING A LATERAL-EPITAXIAL-OVERGROWTH THIN-FILM LIGHT-EMITTING DIODE WITH NANOSCALE-ROUGHENED STRUCTURE

(71) Applicant: National Chiao Tung University, Hsinchu City (TW)

(72) Inventors: Chia-Yu LEE, Chiayi City (TW); Chao-Hsun WANG, Jhongli City (TW); Ching-Hsueh CHIU, New Taipei City (TW); Hao-Chung KUO, Hsinchu City (TW)

(21) Appl. No.: 14/460,922

(22) Filed: Aug. 15, 2014

Related U.S. Application Data
(62) Division of application No. 13/167,406, filed on Jun. 23, 2011.

(30) Foreign Application Priority Data
Apr. 26, 2011 (TW) 100114489

(51) Int. Cl. H01L 33/22; H01L 33/06; H01L 33/00

(52) U.S. Cl. CPC H01L 33/22; H01L 33/007; H01L 33/06; H01L 33/0095
USPC 438/29

(57) ABSTRACT

A method for fabricating a lateral-epitaxial-overgrowth thin-film LED with a nanoscale-roughened structure is provided. The lateral-epitaxial-overgrowth thin-film LED with a nanoscale-roughened structure has a substrate, a metal bonding layer formed on the substrate, a first electrode formed on the metal bonding layer, a semiconductor structure formed on the first electrode with a lateral-epitaxial-growth technology, and a second electrode formed on the semiconductor structure. A nanoscale-roughened structure is formed on the semiconductor structure except the region covered by the second electrode. Lateral epitaxial growth is used to effectively inhibit the stacking faults and reduce the thread dislocation density in the semiconductor structure to improve the crystallization quality of the light-emitting layer and reduce leakage current. Meanwhile, the surface roughened structure on the semiconductor structure can promote the external quantum efficiency.

### CROSS-REFERENCE TO RELATED APPLICATIONS

This application is a Divisional of co-pending application Ser. No. 13/167,406, filed on Jun. 23, 2011, for which priority is claimed under 35 U.S.C. §120; and this application claims priority of Application No. 100114489, filed in Taiwan, R.O.C. on Apr. 26, 2011 under 35 U.S.C. §119, the entire contents of all of which are hereby incorporated by reference.

### BACKGROUND OF THE INVENTION

1. Field of the Invention

The present invention relates to a thin-film LED and a method for fabricating the same, particularly to a lateral-epitaxial-overgrowth thin-film LED with a nanoscale-roughened structure and a method for fabricating the same.

2. Description of the Related Art

Using a laser lift-off method to fabricate GaN LED (Light Emitting Diode) can effectively improve heat radiation in chip level and obviously reduce the efficiency droop caused by poor heat radiation. Further, the laser lift-off method also increases the light-emitting area of LED. Therefore, the laser lift-off method has been the mainstream technology to fabricate high-power LED. In a paper “Effects of Laser Sources on the Reverse-Bias Leakages of Laser Lift-Off Gan-Based Light-Emitting Diodes”, by Yewchung Sermon Wu, Ji-Hao Cheng, and Wei Chih Peng, in APPLIED PHYSICS LETTERS 90, 251110 (2007), it was found that the stress release caused by the laser lift-off method increases dislocations, which not only decreases the light-emitting efficiency but also shortens the service life. Although the prior art instructed the methods for promoting the epitaxy quality of GaN and increasing the light extraction efficiency thereof, the process is too complicated to realize. It was pointed that using a patterned sapphire substrate to fabricate LED not only can promote the light extraction efficiency but also can decrease the dislocation density of epitaxy, in a paper “Enhanced Output Power of Near-Ultraviolet”, by D. S. Wuu, W. K. Wang, W. C. Shih, R. H. Horng, C. E. Lee, W. Y. Lin, and J. S. Fang in IEEE PHOTONICS TECHNOLOGY LETTERS, VOL. 17, NO. 2, February 2005, and in a paper “Enhancing the Output Power of GaN-Based LEDs Grown on Wet-Etched Patterned Sapphire Substrates”, by Y. J. Lee, J. M. Hwang, T. C. Hsu, M. H. Hsieh, M. J. Jou, B. J. Lee, T. C. Lu, H. C. Kuo, Member, IEEE, and S. C. Wang, Senior Member, IEEE, in IEEE PHOTONICS TECHNOLOGY LETTERS, VOL. 18, NO. 10, May 15, 2006. In a paper “Enhancement of the Light Output Power of InGaN GaN Light Emitting Diodes Grown on Pyramidal Patterned Sapphire Substrates in the Micro and Nanoscale”, by Haiyong Gao, Fawang Yan, Yang Zhang, Jinmin Li, Yiping Zeng, and Guohong Wang, in JOURNAL OF APPLIED PHYSICS 103, 014314 (2008), it was pointed out that using a nanoscale-patterned sapphire substrate to fabricate LED can improve the epitaxy quality of GaN. However, the conventional technology uses photolithography to etch patterns, which increases the fabrication complexity and thus raises the fabrication cost.

Accordingly, the present invention proposes a lateral-epitaxial-overgrowth thin-film LED with a nanoscale-roughened structure and a method for fabricating the same to overcome the abovementioned problems.

### SUMMARY OF THE INVENTION

The primary objective of the present invention is to provide a lateral-epitaxial-overgrowth thin-film LED with a nanoscale-roughened structure and a method for fabricating the same, wherein the semiconductor structure thereof is grown in a lateral-epitaxial-overgrowth way on an epitaxy substrate having a nanoscale-patterned silicon oxide layer, whereby are inhibited the stacking faults in epitaxially growing the semiconductor structure, decreased the thread dislocation density, and increased the crystallization quality of the light-emitting semiconductor layer.

Another objective of the present invention is to provide a lateral-epitaxial-overgrowth thin-film LED with a nanoscale-roughened structure and a method for fabricating the same, which can promote the external quantum efficiency without roughening the light-outgoing face of the semiconductor structure once again.

A further objective of the present invention is to provide a lateral-epitaxial-overgrowth thin-film LED with a nanoscale-roughened structure and a method for fabricating the same, which needn't use photolithography to etch patterns, whereby is greatly reduced the complexity and cost of fabrication.

To achieve the abovementioned objectives, the present invention proposes a lateral-epitaxial-overgrowth thin-film LED with a nanoscale-roughened structure, which comprises a substrate; a metal bonding layer formed on the substrate; a first electrode formed on the metal bonding layer; a semiconductor structure grown on the first electrode with a lateral-epitaxial-overgrowth technology; and a second electrode formed on the semiconductor structure, wherein a nanoscale-roughened structure is formed on the semiconductor structure except a region covered by the second electrode.

The present invention also proposes a method for fabricating a lateral-epitaxial-overgrowth thin-film LED with a nanoscale-roughened structure, which comprises steps: providing an epitaxy substrate having a nanoscale-patterned silicon oxide layer; growing a semiconductor structure on the nanoscale-patterned silicon oxide layer with a lateral-epitaxial-overgrowth technology, wherein a nanoscale-roughened structure corresponding to the nanoscale-patterned silicon oxide layer is formed on the semiconductor structure; forming a first electrode on the semiconductor structure; providing a second substrate having a metal bonding layer; joining the first electrode to the metal bonding layer, and removing the epitaxy substrate to reveal the nanoscale-roughened structure of the semiconductor structure; and forming a second electrode on the semiconductor structure.

Below, embodiments are described in detail to make easily understood the objectives, technical contents, characteristics and accomplishments of the present invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram schematically showing the structure of a lateral-epitaxial-overgrowth thin-film LED with a nanoscale-roughened structure according to one embodiment of the present invention;

FIGS. 2(a)-2(f) are sectional views schematically showing the steps of fabricating a lateral-epitaxial-overgrowth thin-film LED with a nanoscale-roughened structure according to one embodiment of the present invention;

FIG. 3 shows an SEM (scanning electron microscope) image of a nanoscale-patterned silicon oxide layer according to one embodiment of the present invention;

FIG. 4(a) shows a TEM image of a conventional thin-film LED;

FIG. 4(b) shows a TEM image a TEM image of a thin-film LED according to one embodiment of the present invention;

FIG. 5(a) shows an C-AFM image of a thin-film LED according to one embodiment of the present invention;

FIG. 5(b) shows an C-AFM image of a conventional thin-film LED; and

FIG. 6 shows current-output intensity relationships of a conventional thin-film LED and a thin-film LED according to one embodiment of the present invention.

### DETAILED DESCRIPTION OF THE INVENTION

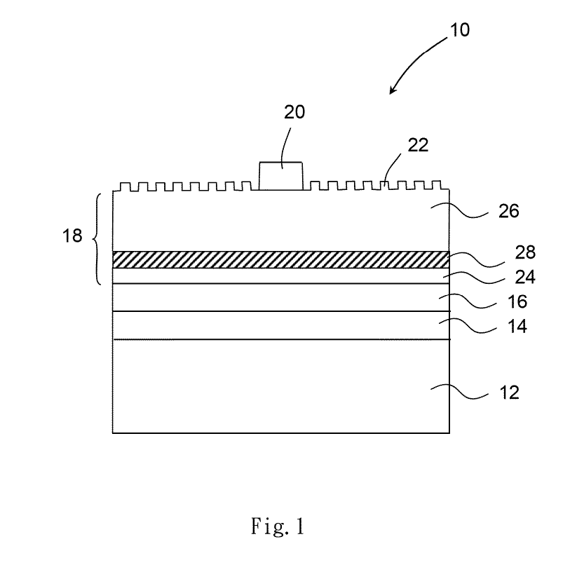

Refer to FIG. 1 for the structure of a lateral-epitaxial-overgrowth thin-film LED with a nanoscale-roughened structure according to one embodiment of the present invention. The lateral-epitaxial-overgrowth thin-film LED 10 with a nanoscale-roughened structure of the present invention comprises a substrate 12; a metal bonding layer 14 formed on the substrate 12; a first electrode 16 formed on the metal bonding layer 14; a semiconductor structure 18 formed on the first electrode 16; and a second electrode 20 formed on the semiconductor structure 18, wherein the upper surface of the semiconductor structure 18 has a nanoscale-roughened structure 22 except the area covered by the second electrode 20.

The metal bonding layer 14 is a dual-layer structure having a titanium layer and a gold layer bottom up. The first electrode 16 is a three-layer structure having a gold layer, a platinum layer and a chromium layer bottom up. Thus, the gold layer of the metal bonding layer 14 contacts the gold layer of the first electrode 16. The second electrode 20 is a dual-layer structure having a gold layer and a chromium layer bottom up. The substrate 12 adopts a silicon substrate or a metallic substrate, which can radiate heat easily.

The semiconductor structure 18 can be electrically induced to emit light. The semiconductor structure 18 has a P-type III-V group semiconductor layer 24; an N-type III-V group semiconductor layer 26 with the nanoscale-roughened structure 22 formed on the surface thereof; and a light-emitting semiconductor layer 28 formed between the P-type III-V group semiconductor layer 24 and the N-type III-V group semiconductor layer 26 and containing a multi-quantum well structure. The abovementioned III-V group semiconductor may be gallium nitride or gallium phosphide.

The nanoscale-roughened structure 22 has nanoscale regular or irregular geometrical patterns. When the nanoscale-roughened structure has regular geometrical patterns, the regular geometrical patterns may be a plurality of nanoscale circles, nanoscale ellipses, or nanoscale polygons, which have a period or size of 0.01-0.9 nm.

In the present invention, the nanoscale-roughened structure 22 formed on the N-type III-V group semiconductor layer 26 promotes the light extraction efficiency of the lateral-epitaxial-overgrowth thin-film LED 10 with a nanoscale-roughened structure, and the wavelength of the peak is within a given range.

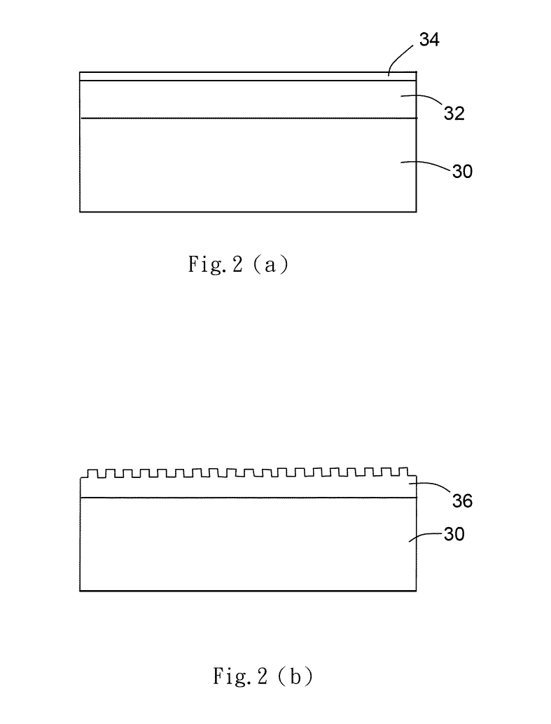

Refer to FIGS. 2(a)-2(f) sectional views schematically showing the steps of fabricating a lateral-epitaxial-overgrowth thin-film LED with a nanoscale-roughened structure according to one embodiment of the present invention. Refer to FIG. 2(a). Firstly, provide an epitaxy substrate 30, and form on the epitaxy substrate 30 a silicon oxide layer 32 having a thickness of 200 nm with a vapor deposition method, and then form on the silicon oxide layer 32 a nickel layer 34 having a thickness of 50 nm with a vapor deposition method.

Refer to FIG. 2(b). Next, perform an annealing treatment at a temperature of 850° C. for one minute to make the nickel particles of the nickel layer 34 aggregate to form a nanoscale-patterned mask. Next, etch the silicon oxide layer 32 through the nanoscale-patterned mask. The etching may be undertaken with a reaction ion etching (RIE) system for 3 minutes. Next, remove the nanoscale-patterned mask with a nitric acid solution to form a nanoscale-patterned silicon oxide layer 36 containing patterns with diameters of about 100-150 nm.

Refer to FIG. 2(c). Next, use a metal organic chemical vapor deposition (MOCVD) method to epitaxially grow on the nanoscale-patterned silicon oxide layer 36 in sequence an N-type III-V group semiconductor layer 26, a light-emitting semiconductor layer 28 containing a multi-quantum well structure, and a P-type III-V group semiconductor layer 24 to form a semiconductor structure 18. The bottom surface of the N-type III-V group semiconductor layer 26 thus has a nanoscale-roughened structure 22 corresponding to the patterns of the nanoscale-patterned silicon oxide layer 36. The epitaxy substrate 30 is made of a material having lattice constants similar to those of the semiconductor structure, such as sapphire.

In order to epitaxially grow the semiconductor structure 18 easily, a gallium nitride buffer layer (not shown in the drawings) having a thickness of about 50 nm is formed on the epitaxy substrate 30 before the semiconductor structure 18 is formed, in one embodiment of the present invention.

In the present invention, the semiconductor structure 18 is on the nanoscale-patterned silicon oxide layer 36 with a lateral-epitaxial-overgrowth technology. Therefore, the present invention can effectively inhibit the stacking faults occurring in epitaxial growth, decrease the thread dislocation density, promote the crystallization quality of the light-emitting semiconductor layer 28, and reduce the leakage current. The light-outgoing face of the N-type III-V group semiconductor layer 26 has possessed a nanoscale-roughened structure 22 in this stage. Therefore, it is unnecessary for the present invention to perform a roughening process once again to increase the external quantum efficiency.

Refer to FIG. 2(d). Next, form a first electrode 16 on the semiconductor structure 18 with a chemical or physical vapor deposition method.

Refer to FIG. 2(e). Next, provide a substrate 12 having a metal bonding layer 14, and join the first electrode 16 to the metal bonding layer 14 with a high-temperature and high-pressure process.

Next, remove the epitaxy substrate 30 and the nanoscale-patterned silicon oxide layer 36 from the semiconductor structure 18 with a laser lift-off method. The laser lift-off method may be realized by using an excimer laser having a wavelength of 248 nm and a pulse width of 25 ns to illuminate and damage the buffer layer, whereby the epitaxy substrate 30 and the nanoscale-patterned silicon oxide layer 36 can be separated from the semiconductor structure 18.

Refer to FIG. 2(f). Next, sequentially use sulfuric acid and plasma to remove the residual gallium nitride buffer layer on the semiconductor structure 18. Next, remove a part of the nanoscale-roughened structure 22, and form a second electrode 20 on the area where the nanoscale-roughened structure 22 is removed. Thus is completed the LED of the present invention.

Before the second electrode 20 is formed, an inductively-coupled plasma (ICP) may be used to etch the semiconductor structure from the surface downward to the first electrode so as to divide the structure into a plurality of LED chips.

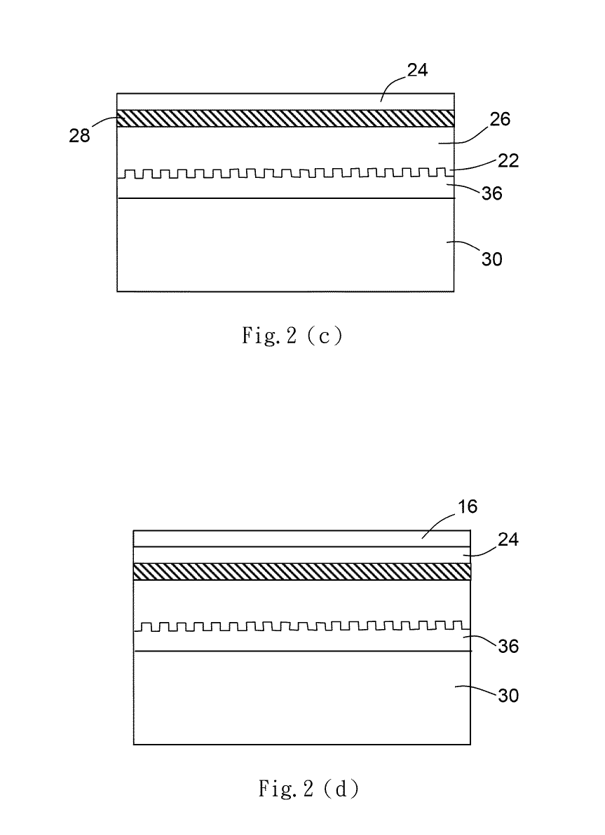

Refer to FIG. 3 showing an SEM (Scanning Electron Microscope) image of a nanoscale-patterned silicon oxide layer containing nanocolumns having diameters of about 100-150 nm.

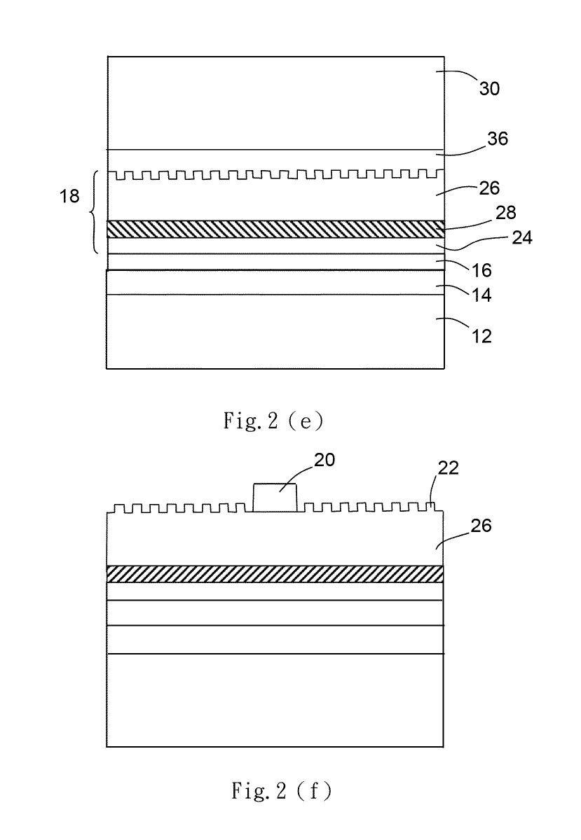

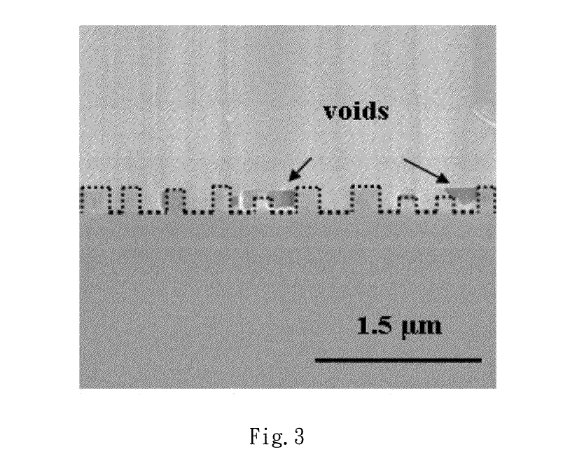

Refer to FIG. 4(a) and FIG. 4(b) respectively showing a TEM (Transmission Electron Microscope) image of a conventional thin-film LED and a TEM image of a thin-film LED of the present invention. It is observed that the conventional thin-film LED has higher thread dislocation density than the thin-film LED of the present invention.

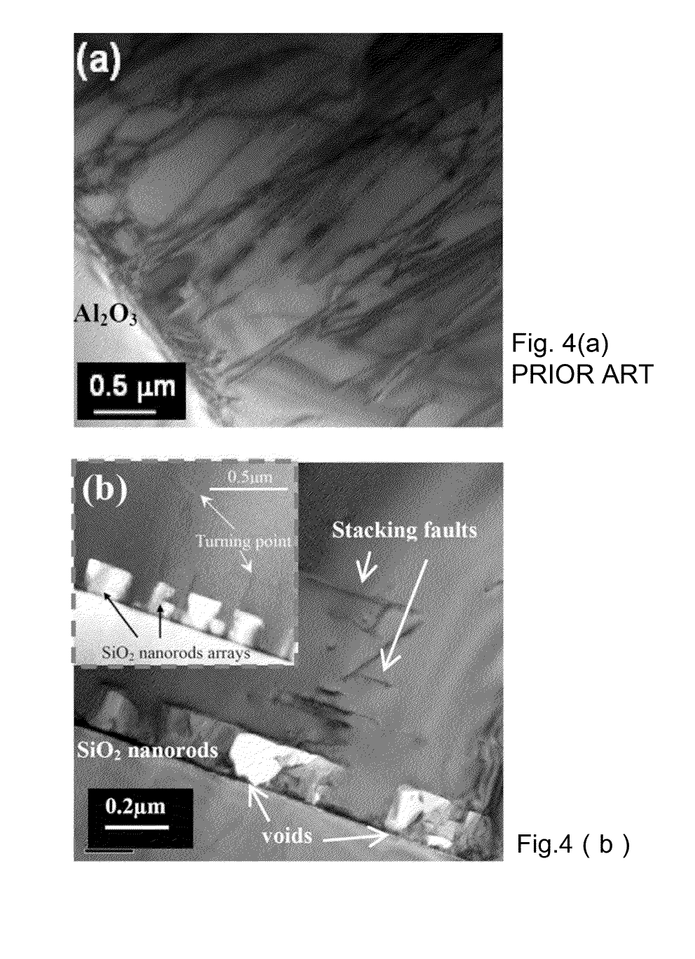

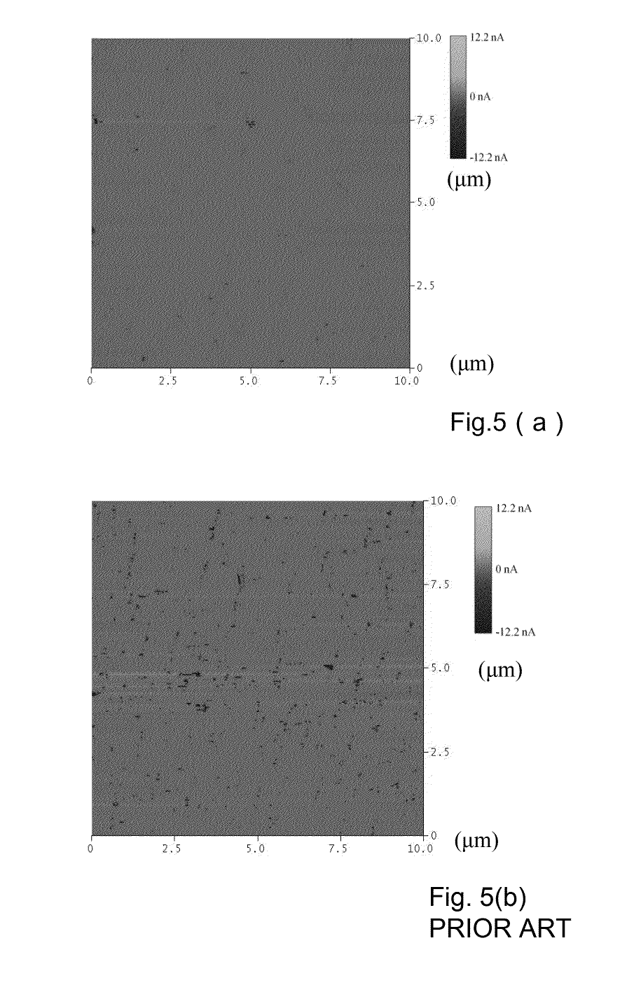

Refer to FIG. 5(a) and FIG. 5(b) respectively showing an C-AFM image of a conventional thin-film LED and an C-AFM image of a thin-film LED of the present invention. It is observed that the conventional thin-film LED has larger area of leakage current than the thin-film LED of the present invention.

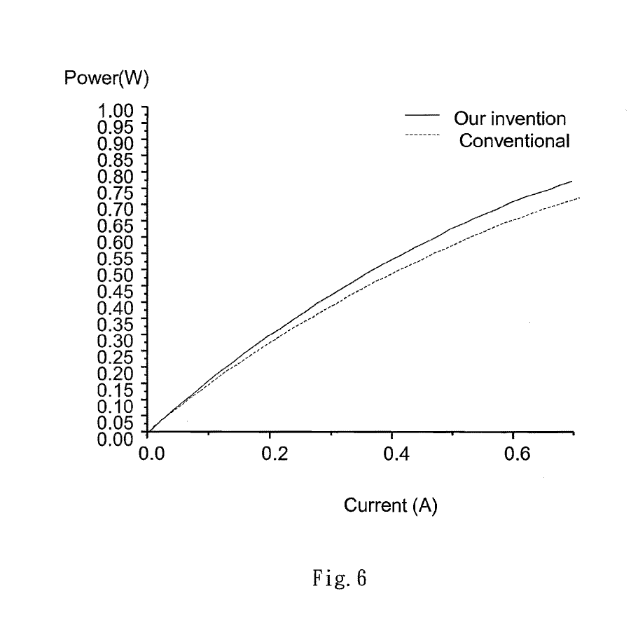

Refer to FIG. 6 showing current-output intensity relationships of a conventional thin-film LED and a thin-film LED of the present invention. It is observed that the lateral-epitaxial-overgrowth thin-film LED with a nanoscale-roughened structure of the present invention outperforms the conventional thin-film LED in the power of output light at any value of current.

In conclusion, the present invention proposes a lateral-epitaxial-overgrowth thin-film LED with a nanoscale-roughened structure and a method for fabricating the same, wherein the semiconductor structure thereof is formed on an epitaxy substrate having a nanoscale-patterned silicon oxide layer with a lateral-epitaxial-overgrowth technology, whereby are inhibited the stacking faults in epitaxially growing the semiconductor structure, decreased the thread dislocation density, and increased the crystallization quality of the light-emitting semiconductor layer. Further, the method of the present invention can increase the external quantum efficiency without roughening the light-outgoing face of the semiconductor structure once again. Furthermore, the structure of the present invention favors applying the laser lift-off method to the thin-film LED and thus promotes the yield thereof

Moreover, the method of the present invention needn't use photolithography to etch patterns and thus greatly decreases the complexity and cost of fabrication.

The embodiments described above are only to exemplify the present invention but not to limit the scope of the present invention. Any equivalent modification or variation according to the characteristics or spirit of the present invention is to be also included within the scope of the present invention.

What is claimed is:

1. A method for fabricating a lateral-epitaxial-overgrowth thin-film light emitting diode with a nanoscale-roughened structure, comprising steps:
providing an epitaxy substrate having a nanoscale-patterned silicon oxide layer;
growing a semiconductor structure on said nanoscale-patterned silicon oxide layer with a lateral-epitaxial-overgrowth technology, wherein a nanoscale-roughened structure corresponding to said nanoscale-patterned silicon oxide layer is formed on said semiconductor structure;
forming a first electrode on said semiconductor structure;
providing a second substrate having a metal bonding layer;
joining said first electrode to said metal bonding layer, and removing said epitaxy substrate to reveal said nanoscale-roughened structure of said semiconductor structure; and
forming a second electrode on said semiconductor structure.

2. The method for fabricating a lateral-epitaxial-overgrowth thin-film light emitting diode with a nanoscale-roughened structure according to claim 1, wherein steps for fabricating said nanoscale-patterned silicon oxide layer include
sequentially forming a silicon oxide layer and a nanoscale-thickness metal layer on said epitaxy substrate;
performing an annealing treatment to make metallic particles of said nanoscale-thickness metal layer aggregate to form a nanoscale-patterned mask; and
etching said silicon oxide layer through said nanoscale-patterned mask, and then removing said nanoscale-patterned mask to form said nanoscale-patterned silicon oxide layer.

3. The method for fabricating a lateral-epitaxial-overgrowth thin-film light emitting diode with a nanoscale-roughened structure according to claim 1, wherein steps for fabricating said semiconductor structure include
depositing an N-type III-V group semiconductor layer;
depositing a light-emitting semiconductor layer having a multi-quantum well structure; and
depositing a P-type III-V group semiconductor layer.

4. The method for fabricating a lateral-epitaxial-overgrowth thin-film light emitting diode with a nanoscale-roughened structure according to claim 1, wherein removing said epitaxy substrate is realized with a laser lift-off method.

5. The method for fabricating a lateral-epitaxial-overgrowth thin-film light emitting diode with a nanoscale-roughened structure according to claim 1, wherein said nanoscale-roughened structure has regular geometrical patterns or irregular geometrical patterns.

6. The method for fabricating a lateral-epitaxial-overgrowth thin-film light emitting diode with a nanoscale-roughened structure according to claim 1, wherein said nanoscale-roughened structure has regular patterns of nanoscale circles, nanoscale ellipses or nanoscale polygons.

7. The method for fabricating a lateral-epitaxial-overgrowth thin-film light emitting diode with a nanoscale-roughened structure according to claim 1, wherein said nanoscale-roughened structure has regular geometrical patterns with a period or size of 0.01-0.9 nm.
